(19) United States
(12) Patent Application Publication
(10) Pub. No.: US 2008/0164511 A1
(43) Pub. Date: Jul. 10, 2008

(54) SEMICONDUCTOR DEVICE

(76) Inventor: Sung-Jin Kim, Busan (KR)

Correspondence Address: SHERR & NOURSE, PLLC, 620 HERNDON PARKWAY, SUITE 200, HERNDON, VA, 20170, US

(21) Appl. No.: 11/963,372

(22) Filed: Dec. 21, 2007

(30) Foreign Application Priority Data
Dec. 29, 2006 (KR) 10-2006-0137352

(51) Int. Cl. H01L 27/088; H01L 21/28

(52) U.S. Cl. 257/321; 438/588; 257/E27.06; 257/E21.179

(57) ABSTRACT

A semiconductor device having spacer patterns formed at the sidewalls of gate electrodes and a method of fabricating the same are disclosed. The semiconductor device includes a gate pattern, including a plurality of gate electrodes, formed on a semiconductor substrate, a barrier insulation layer formed on the entire surface of the substrate including the gate pattern, and spacer patterns formed at opposite sidewall regions of the respective gate electrodes surrounded by the barrier insulation layer such that the spacer patterns have a height less than that of the respective gate electrodes.

The present application claims priority under 35 U.S.C. 119 and 35 U.S.C. 365 to Korean Patent Application No. 10-2006-0137352 (filed on Dec. 29, 2006), which is hereby incorporated by reference in its entirety.

### BACKGROUND

As semiconductor devices have become more highly integrated, the space between patterns may become narrower. Hence, filling the space with an interlayer insulation layer for interlayer insulation between wires may become more difficult.

In a semiconductor device cell array in which the semiconductor device may be formed with a minimum line width and pitch, the line width of a trench region for a device isolation layer and the distance between word lines may become rapidly reduced. The distance between the word lines may be greatly reduced, to such an extent that gap fill may not be easily accomplished, due to spacer patterns formed at the sidewalls of the word lines.

When filling the trench region or the gap between the word lines, the gap fill may be greatly affected by the width and the aspect ratio of the gap. When the aspect ratio is 4:1 or more, and the width of the gap is 100 nm or less, the gap may not be completely filled, and a void may be created.

In a flash memory device, word lines may have a large vertical size due to their structural characteristics, with the result that the aspect ratio at the gap between the word lines may be greater than that of other devices. Furthermore, since the word lines have a profile in which the width at the upper parts of the word lines is greater than that at the lower parts of the word lines, the gap between the word lines may be narrow at the regions adjacent to a substrate, whereby the interlayer insulation layer may not be fully gap-filled, and therefore, a void may be created.

FIGS. 1 and 2 are sectional drawings illustrating a method of fabricating a related art semiconductor device.

Referring to FIG. 1, gate pattern 12, including a plurality of gate electrodes, may be formed on semiconductor substrate 10. First insulation layer 24 and second insulation layer 26, which may be conformable to each other, may be formed on the substrate, on which gate pattern 12 may be formed.

First insulation layer 24 may be made of oxide and tetra-ethyl-ortho-silicate (TEOS), which may be obtained by the oxidation of sidewalls of gate pattern 12, whereas second insulation layer 26 may be made of silicon nitride.

Referring to FIG. 2, second insulation layer 26 may be anisotropically etched to form spacer patterns 26s at the sidewalls of gate pattern 12. Spacer patterns 26s may be formed by etching the second insulation layer 26, while using first insulation layer 24 as an etching prevention layer, in an etching condition having a high selectivity.

When the line width of the gate electrodes and the distance between the gate electrodes may be reduced to 90 nm or less at gate pattern 12, a gap having a high aspect ratio may be formed between the gate electrodes having a height of 300 nm or more. Especially, the width of the gate electrodes may be greatly reduced at a region adjacent to the substrate between the gate electrodes due to the structural characteristics of the spacer patterns 26s.

Consequently, if interlayer insulation layer 28 is formed, the gap defined between spacer patterns 26s at the opposite gate electrodes of gate pattern 12 may not be fully filled with interlayer insulation layer 28, with the result that a void 30 may be created.

If the gate electrodes of gate pattern 12 are arranged in a line on the semiconductor substrate such that the electrodes are parallel to each other, the void may be created between the gate electrodes while the void may be in parallel to the gate electrodes. Consequently, if contact patterns, connected to the semiconductor substrate through interlayer insulation layer 28, are formed between the respective gate electrodes, conductive film may penetrate into void 30. As a result, short circuits may occur at the contact patterns.

### SUMMARY

Embodiments relate to a semiconductor device and a method of fabricating the same, and more particularly, to a semiconductor device having spacer patterns formed at the sidewalls of gate electrodes and a method of fabricating the same.

Embodiments may relate to a semiconductor device having substantially no void created in an interlayer insulation layer between gate electrodes constituting a gate pattern and a method of fabricating the same.

Embodiments relate to a semiconductor device having spacer patterns of a small aspect ratio formed, in a gap region where an interlayer insulation layer may be filled, at the sidewalls of gate electrodes constituting a gate pattern and a method of fabricating the same.

According to embodiments, a semiconductor device may includes a gate pattern, including a plurality of gate electrodes, formed on a semiconductor substrate, a barrier insulation layer formed on a surface, for example the entire surface, of the substrate including the gate pattern, and spacer patterns formed at opposite sidewall regions of the respective gate electrodes surrounded by the barrier insulation layer such that the spacer patterns have a height less than that of the respective gate electrodes.

According to embodiments, a method of fabricating a semiconductor device may include forming a gate pattern, including a plurality of gate electrodes, on a semiconductor substrate, forming a barrier insulation layer on a surface, for example the entire surface, of the substrate including the gate pattern, forming a spacer insulation layer on a surface, for example the entire surface, of the substrate where the barrier insulation layer may be formed, and forming spacer patterns at opposite sidewall regions of the respective gate electrodes such that the spacer patterns have a height less than that of the respective gate electrodes.

According to embodiments, forming the spacer patterns may include forming mask patterns on the spacer insulation layer such that the mask patterns extend, by a predetermined width, from the barrier insulation layer at the sidewalls of the respective gate electrodes, and anisotropically etching the spacer insulation layer using the mask patterns as an etching mask.

### DRAWINGS

FIGS. 1 and 2 are process drawings, in section, illustrating a method of fabricating a related art semiconductor device.

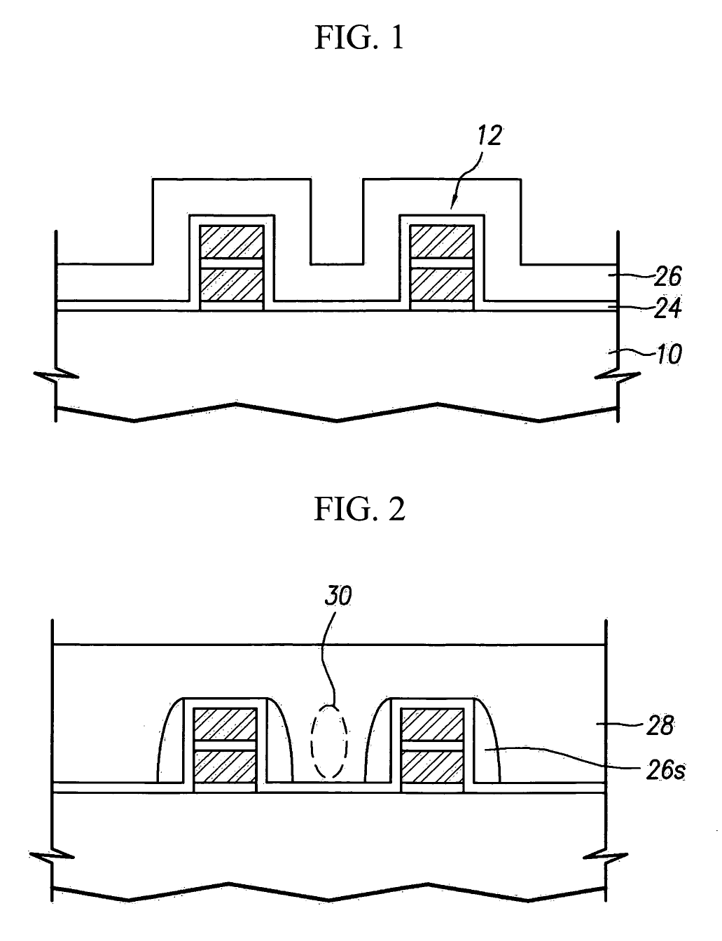

FIG. 3 is a sectional drawing illustrating a semiconductor device according to embodiments.

FIGS. 4 to 6 are process drawings, in section, illustrating a method of fabricating a semiconductor device according to embodiments.

### DESCRIPTION

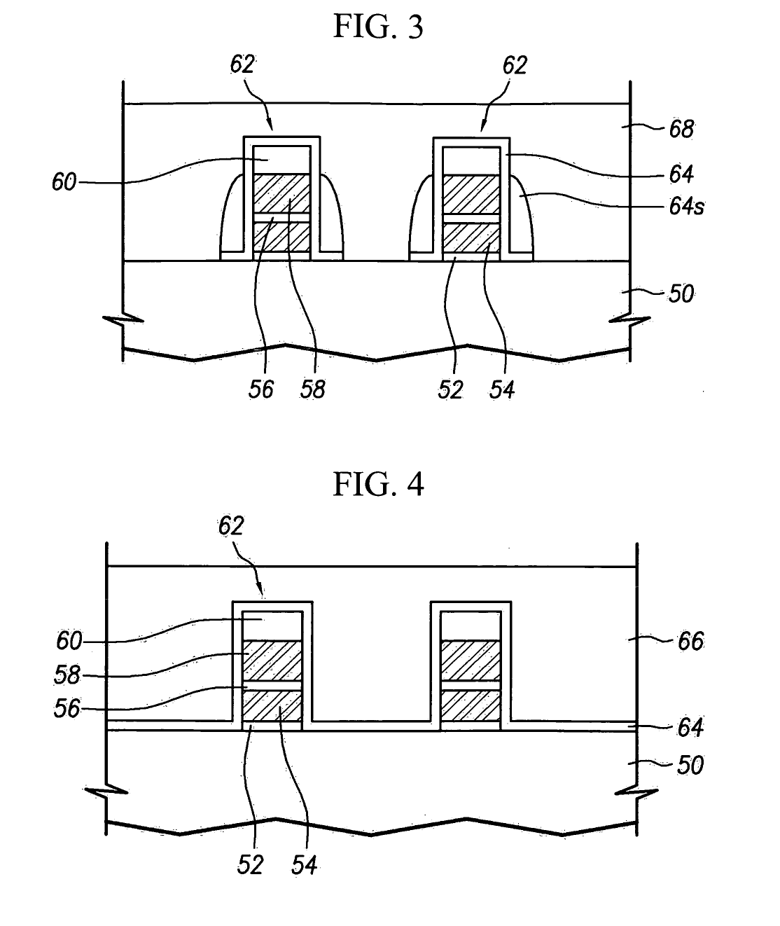

Referring to FIG. 3, a gate pattern, including a plurality of gate electrodes 62, may be formed on semiconductor substrate 50. According to embodiments, gate electrodes 62 may be arranged on semiconductor substrate 50 in a structure in which gate electrodes 62 may be parallel to each other or in a complicated plane structure.

According to embodiments, in a memory device cell array, gate electrodes 62 may be arranged with a minimum line width and at a minimum interval. Embodiments may relate to a flash memory device, which may be a nonvolatile memory device. According to embodiments, each gate electrode 62 may include tunnel insulation layer 52, floating gate 54, intergate dielectric layer 56, and control gate electrode 58, which may be sequentially stacked from bottom to top. Each gate electrode 62 may further include capping insulation layer 60 formed at the uppermost layer of gate electrode 62, i.e., on control gate electrode 58.

Capping insulation layer 60 may be provided to prevent the occurrence of a short circuit between the gate electrode and a reflection preventing layer and a following contact plug when the reflection preventing layer and the contact plug may be formed.

According to embodiments, barrier insulation layers 64 may be formed on a surface, for example the entire surface, of the substrate including the gate pattern. As a result, the sidewall and the top of each gate electrode 62 may be covered with corresponding barrier insulation layer 64. Subsequently, spacer pattern 66s may be formed at the sidewall region of each gate electrode 62 surrounded by the corresponding barrier insulation layer 64.

Barrier insulation layer 64 serves as an etching prevention layer during the formation of spacer pattern 66s. If spacer pattern 66s is made of silicon nitride, barrier insulation layer 64 may also serve to isolate gate electrode 62 from the stress of the silicon nitride. This may prevent the occurrence of traps and defects.

Spacer pattern 66s may be formed at the lower end of corresponding gate electrode 62 such that the height of spacer pattern 66s may be less than that of corresponding gate electrode 62. Consequently, the total aspect ratio may be decreased due to the remaining region where spacer pattern 66s may not be formed. According to embodiments, spacer pattern 66s may cover barrier insulation layer 64 at the sidewall of control gate electrode 66. According to embodiments, spacer pattern 66s may be formed on barrier insulation layer 64 formed at the side wall of the corresponding gate electrode; however, the region where spacer pattern 66s may be formed below capping insulation layer 60.

Interlayer insulation layer 68 may be formed on a surface, for example the entire surface, of the substrate where spacer patterns 66s may be formed.

Gap fill may be easily accomplished on interlayer insulation layer 68, especially between the upper parts of gate electrodes 62 where spacer patterns 66s may not be formed. Furthermore, gap fill may be also easily accomplished between the lower parts of gate electrodes 62 where spacer patterns 66s may be formed, because the aspect ratio may be decreased although the width between gate electrodes 62 may be small.

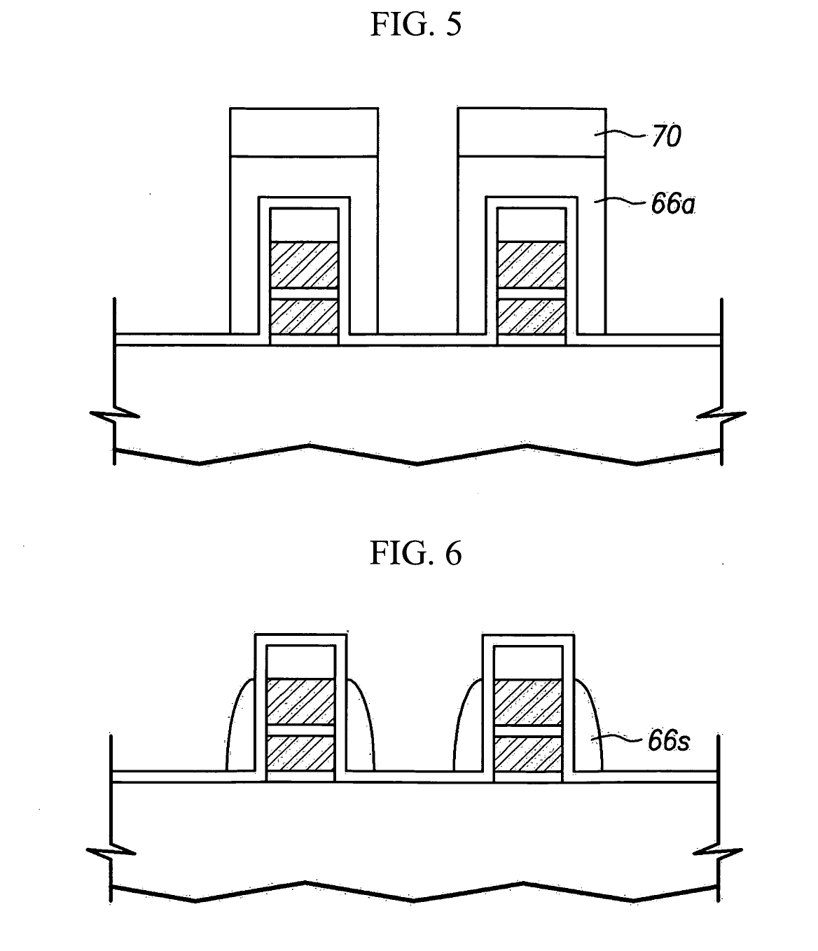

FIGS. 4 to 6 are process drawings, in section, illustrating a method of fabricating a semiconductor device according to embodiments. Specifically, embodiments may relate to a flash memory device, although embodiments are not limited to the flash memory device.

Referring to FIG. 4, a gate pattern, including a plurality of gate electrodes 62, may be formed on semiconductor substrate 50.

According to embodiments, each gate electrode 62 may include floating gate 54, intergate dielectric layer 56, control gate electrode 58, and capping insulation layer 60, which may be sequentially stacked on tunnel insulation layer 52, which may be the lowermost layer of gate electrode 62.

Although not shown, dopant may be injected into semiconductor substrate 50 to form a well region, and then a device insulation layer may be formed to define a plurality of parallel active regions on the semiconductor substrate.

According to embodiments, gate electrodes 62 may be arranged across the active regions and the top of the device insulation layer. According to embodiments, gate electrodes 62 may be arranged on the cell array such that gate electrodes 62 may be parallel to each other.

Barrier insulation layer 64 may be formed to cover the sidewall and the top of gate electrode 62.

Barrier insulation layer 64 may include TEOS. The TEOS may be deposited, by chemical vapor deposition, together with thermal oxide formed at the sidewall of each gate electrode 62 in an oxidation process for recovering the etching damage during the formation of gate electrode 62.

Spacer insulation layer 66 may be formed on a surface, for example the entire surface, of the substrate where barrier insulation layer 64 may be formed. According to embodiments, a gap defined between gate electrodes 62 may be filled with spacer insulation layer 66.

The portion of spacer insulation layer 66 located at the middle between gate electrodes 62 may be removed. According to embodiments, although a void may be created during the formation of spacer insulation layer 66, the void may be removed afterward.

According to embodiments, spacer insulation layer 66 may be made of a material having an etching selectivity with respect to barrier insulation layer 64. That is, spacer insulation layer 66 may be made of a material different from that of barrier insulation layer 64. Since barrier insulation hyer 64 may be made of oxide, therefore, spacer insulation layer 66 may be made of nitride.

Referring to FIG. 5, mask patterns 70 may be formed on spacer insulation layer 66. Spacer insulation layer 66 may be etched using mask patterns 70 as an etching mask. Mask patterns 70 may be made of photoresist.

According to embodiments, mask patterns 70 may be arranged at the tops of respective gate electrodes 62 and extend to opposite sides of respective gate electrodes 62, such that mask patterns 70 may be formed on spacer insulation layer 66, while mask patterns 70 have a width greater than that of gate electrodes 62.

According to embodiments, mask patterns 70 may extend to the opposite sides of gate electrodes 62 including the gate electrodes 62 and barrier insulation layer 64. That is, mask patterns 70 may be formed such that mask patterns 70 have a width greater than that of the part formed at the sidewall of each gate electrode 62 at barrier insulation layer 64. Through the etching process using mask patterns 70, spacer insulation layer 66 may be etched such that the width of spacer insulation layer 66 may be greater by a predetermined width in the lateral direction than the part formed at the sidewall of each gate electrode 62 at barrier insulation layer 64.

According to embodiments, an anisotropic etching process may be carried out using mask patterns 70 as an etching mask. Through the anisotropic etching process, parts 66a, which may have a predetermined width from barrier insulation layer 64 in the lateral direction, of spacer insulation layer 66 may be left while the remaining region of spacer insulation layer 66, including the region between gate electrodes 62, may be removed.

Referring to FIG. 6, mask patterns 70 may be removed to expose the tops of spacer insulation layers 66a.

Spacer insulation layers 66a may be formed with a large thickness sufficient to cover the top of the gate pattern. According to embodiments, on the other hand, the parts of spacer insulation layers 66a between gate electrodes 62 may be formed with a small thickness to decrease the aspect ratio.

Spacer insulation layers 66a, from which mask patterns 70 may be removed, may be etchbacked to remove spacer insulation layers 66a covering the top of the gate pattern. In the removing process, the spacer insulation layers formed at the sidewalls of respective gate electrodes 62 may be also etchbacked. As a result, spacer patterns 66s may be formed at barrier insulation layer 64 formed at the lower ends of gate electrodes 62.

According to embodiments, spacer patterns 66s may be formed at positions adjacent to the lower ends of gate electrodes 62. Consequently, the aspect ratio of the gap region defined between gate electrodes 62 may be decreased.

According to embodiments, spacer patterns 66s cover barrier insulation layer 64 formed at the side walls of the control gate electrodes to perform their own function.

According to embodiments, an interlayer insulation layer 68 (see FIG. 3) may be formed on a surface, for example the entire surface, of the substrate where spacer patterns 66s may be formed.

The upper part of the gap region between gate electrodes 62 may be enlarged, and the aspect ration at the lower part of the gap region between the gate electrodes may be decreased. A a result, interlayer insulation layer 68 may be stably filled between the gate electrodes without the creation of a void as shown in FIG. 2.

According to embodiments, the spacer patterns may be only partially formed at the gap region, having a small width, between the gate electrodes constituting the gate pattern. Consequently, the width of the gap may be increased as compared to the related art, and the aspect ratio may be decreased at the region where the width of the gap may not be increased, which may easily accomplish a gap fill.

According to embodiments, the width of the spacer insulation layer remaining at the sidewalls of the respective gate electrodes, may be maximally decreased, before the formation of the spacer pattern, thereby further increasing the width of the gap.

As a result, the creation of a void between the gate electrodes may be prevented, and therefore, the short circuit of the conductive layer through the void may be prevented during the formation of the contact pattern, which may prevent the defectiveness of the device and the reduction of reliability.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device, comprising:
a gate pattern, having a plurality of gate electrodes, formed over a semiconductor substrate;
a barrier insulation layer formed over a surface of the substrate including the gate pattern; and
spacer patterns formed at opposite sidewall regions of respective gate electrodes and surrounded by the barrier insulation layer, wherein the spacer patterns have a height less than that of the respective gate electrodes.

2. The device of claim 1, wherein the spacer patterns comprise material having an etching selectivity with respect to the barrier insulation layer.

3. The device of claim 2, wherein the barrier insulation layer comprises oxide, and the spacer patterns comprise nitride.

4. The device of claim 1, wherein each gate electrode comprises a tunnel insulation layer, a floating gate, an intergate dielectric layer, a control gate electrode, and a capping insulation layer.

5. The device of claim 4, wherein the tunnel insulation layer, the floating gate, the intergate dielectric layer, the control gate electrode, and the capping insulation layer are sequentially stacked from bottom to top.

6. The device of claim 5, wherein the spacer patterns are formed at regions below the corresponding capping insulation layers.

7. The device of claim 6, wherein the spacer patterns are formed at the barrier insulation layer formed at the sidewalls of the gate electrodes below the capping insulation layers.

8. A method, comprising:
forming a gate pattern, including a plurality of gate electrodes, over a semiconductor substrate;
forming a barrier insulation layer over a surface of the substrate including the gate pattern;
forming a spacer insulation layer over the surface of the substrate where the barrier insulation layer is formed; and
forming spacer patterns at opposite sidewall regions of the respective gate electrodes such that the spacer patterns have a height less than that of the respective gate electrodes.

9. The method of claim 8, wherein forming the spacer patterns comprises:
forming mask patterns over the spacer insulation layer such that the mask patterns extend, by a predetermined width from the barrier insulation layer at the sidewalls of the respective gate electrodes; and
anisotropically etching the spacer insulation layer using the mask patterns as an etching mask.

10. The method of claim 8, wherein a gap defined between the respective gate electrodes of the gate pattern is filled with the spacer insulation layer.

11. The method of claim 8, wherein the spacer insulation layer comprises a material having an etching selectivity with respect to the barrier insulation layer.

12. The method of claim 8, wherein each gate electrode of the gate pattern is formed by stacking a tunnel insulation layer, a floating gate, an intergate dielectric layer, a control gate electrode, and a capping insulation layer.

13. The method of claim 12, wherein the tunnel insulation layer, the floating gate, the intergate dielectric layer, the control gate electrode, and the capping insulation layer are sequentially stacked from bottom to top.

14. A device, comprising:
a plurality of gate electrodes over a semiconductor substrate, each gate electrode comprising a tunnel insulation layer, a floating gate, an intergate dielectric layer, a control gate electrode, and a capping insulation layer;
a barrier insulation layer formed over a surface of the substrate including the gate pattern; and
spacer patterns formed at opposite sidewall regions of respective gate electrodes and surrounded by the barrier insulation layer.

15. The device of claim 14, wherein the spacer patterns have a height less than that of the respective gate electrodes.

16. The device of claim 15, wherein the tunnel insulation layer, the floating gate, the intergate dielectric layer, the control gate electrode, and the capping insulation layer are sequentially stacked from bottom to top.

17. The device of claim 16, wherein the spacer patterns are formed at regions below the corresponding capping insulation layers.

18. The device of claim 17, wherein the spacer patterns are formed at the barrier insulation layer formed at the sidewalls of the gate electrodes below the capping insulation layers.
